(19) United States
(12) Patent Application Publication
(10) Pub. No.: US 2006/0043980 A1
(43) Pub. Date: Mar. 2, 2006

(54) Controllable two layer birefringent optical component

(76) Inventors: Emile Johannes Karel Verstegen, Eindhoven (NL); Hendrik Roelof Stapert, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/540,668

(22) PCT Filed: Dec. 18, 2003
(86) PCT No.: PCT/IB03/06135

§ 371 Date: Jun. 24, 2005

(30) Foreign Application Priority Data
Dec. 30, 2002 (EP) 020805479

(51) Int. Cl. G01R 27/08

(52) U.S. Cl. 324/697

(57) ABSTRACT

An optical component (181) comprises a first birefringent layer (203) connected to a second birefringent layer (170) by a curved interface (206). An optical axis (19) passes through the first and the second layer. The second birefringent layer (170) has molecules movable between a first orientation and a second orientation relative to the optical axis. The refractive index of the second birefringent layer (170) is dependent upon the orientation of the modules.

The present invention relates to a birefringent optical component, a method of manufacturing such a component, and devices including such components. The component is particularly suitable for, but not limited to, use as a variable focus lens in optical scanning devices.

Optical pickup units for use in optical scanning devices are known. The optical pickup units are mounted on a movable support for scanning across the tracks of the optical disk. The size and complexity of the optical pickup unit is preferably reduced as much as practicable, in order to reduce the manufacturing cost and to allow additional space for other components being mounted in the scanning device.

Modern optical pickup units are generally compatible with at least two different formats of optical disk, such as the Compact Disc (CD) and the Digital Versatile Disc (DVD) format. Recently proposed has been the Blu-ray Disk (BD) format, offering a data storage capacity of around 25 GB (compared with a 650 MB capacity of a CD, and a 4.7 GB capacity of a DVD).

Larger capacity storage is enabled by using small scanning wavelengths and large numerical apertures (NA), to provide small focal spots, (the size of the focal spot is approximately λ/(NA), so as to allow the readout of smaller sized marks in the information layer of the disk. For instance, a typical CD format utilizes a wavelength of 785 nm and an objective lens with a numerical aperture of 0.45, a DVD uses a wavelength of 650 nm and a numerical aperture of 0.65, and a BD system uses a wavelength of 405 nm and a numerical aperture of 0.85.

Typically, the refractive index of materials vary as a function of wavelength. Consequently, a lens will provide different focal points and different performance for different incident wavelengths. Further, the discs may have different thickness transparent layers, thus requiring a different focal point for different types of discs.

In some instances, storage capacity is further increased by increasing the number of information layers per disc. For example, a dual layer BD-disc has two information layers separated by a 25 μm thick spacer layer. Thus, the light from the optical pickup unit has to travel through the spacer layer when focusing on the second information layer. This introduces about 255 mλ rms (0.255λ root mean square) of spherical aberration, the phenomenon that rays close to the axis of the converging cone of light have a different focal point compared to the rays on the outside of the cone. This results in a blurring of the focal spot, and a subsequent loss of fidelity in the read-out of the disc.

To enable dual layer readout and backward compatibility (i.e. the same optical system being used for different disc formats), polarization sensitive lenses (PS-Lenses) have been proposed to compensate for spherical aberration. Such lenses can be formed of a birefringent material, such as a liquid crystal. Birefringence denotes the presence of different refractive indices for the two polarization components of a beam of light. Birefringent materials have an extraordinary refractive index (nₑ) and an ordinary refractive index (nₒ), with the difference between the refractive indices being Δn=nₑ−nₒ. PS lenses can be used to provide different focal points for a single or different wavelength(s) by ensuring that the same or different wavelengths are incident upon the lens with different polarization.

A new trend in optical storage is multi-layer or 3D recording. One example of this technique is based upon stacking of multiple fluorescent layers, thus increasing the data storage capacity on one disc. Multi-layer stacks also require light paths that enable accurate focusing of the laser beam at a plurality of specific depths within a disc. Although actuators, present in the optical disc scanning system, do enable the objective lens to move within a certain distance range from the disc (and so enable the focal point to move over a range of distances), such a movement range is limited, and it can not provide the focal depth range required for all proposed multi-layer recording systems.

It is an aim of embodiments of the present invention to provide an improved optical component which addresses one or more of the problems of the prior art, whether referred to herein or otherwise.

It is an aim of particular embodiments of the present invention to provide an optical component comprising two birefringent materials, the optical function of the component being adjustable, as well as a method of manufacturing such a component. Particular embodiments provide an optical lens with a focal point that can be controllably varied over a predetermined range of depths

In a first aspect, the present invention provides an optical component (181) comprising a first birefringent layer (203) connected to a second birefringent layer (170) by a shaped interface (206), an optical axis (19) passing through the first and the second layer, at least the second birefringent layer (170) having molecules movable between a first orientation and a second orientation relative to the optical axis, the refractive index of the second birefringent layer being dependent upon the orientation of the molecules.

By providing an optical component having two such materials, the optical function defined by the interface can be changed by changing the orientation of the molecules. For instance, if the shaped interface is curved, the lens capability provided by the interface can be altered by changing the orientation of the molecules.

In another aspect, the present invention provides an optical scanning device (1) for scanning an information layer (4) of an optical record carrier (2), the device (1) comprising a radiation source (11) for generating a radiation beam (12, 15, 20) and an objective system (18) for converging the radiation beam on the information layer, wherein the device (1) comprises an optical component (181), the optical component comprising a first birefringent layer (203) connected to a second birefringent layer (170) by a shaped interface (206), an optical axis (19) passing through the first and the second layer, at least the second birefringent layer (170) having molecules movable between a first orientation and a second orientation relative to the optical axis, the refractive index of the second birefringent layer being dependent upon the orientation of the modules.

In a further aspect, the present invention provides a method of manufacturing an optical component (181) comprising a first birefringent layer (203) and a second birefringent layer (170), the method comprising: providing a first birefringent layer with a shaped surface (206); providing a second birefringent layer (170) adjacent to the shaped surface (206) of the first birefringent layer;
wherein the molecules of the second birefringent layer are arranged to be movable between a first orientation and a second orientation relative to an optical axis (19) passing through the first birefringent layer (203) and the second birefringent layer (170).

In another aspect, the present invention provides a method of manufacturing an optical scanning device (1) for scanning an information layer (4) of an optical record carrier (2), the method comprising: providing a radiation source (11) for generating a radiation beam (12, 15, 20);
providing an objective system (18) for converging the radiation beam on the information layer; and providing an optical component (181), the optical component comprising a first birefringent layer (203) connected to a second birefringent layer (170) by a shaped interface (206), an optical axis (19) passing through the first and the second layer, at least the second birefringent layer (170) having molecules movable between a first orientation and a second orientation relative to the optical axis, the refractive index of the second birefringent layer being dependent upon the orientation of the modules.

For a better understanding of the invention, and to show how embodiments of the same may be carried into effect, reference will now be made, by way of example, to the accompanying diagrammatic drawings in which:

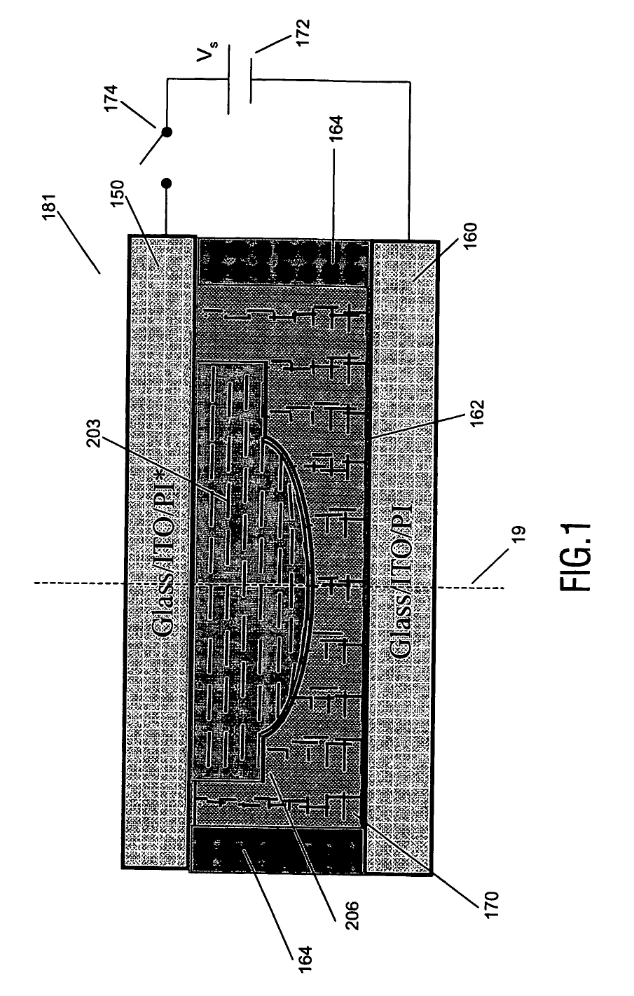

FIG. 1 illustrates a cross sectional view of an optical component in accordance with a preferred embodiment of the present invention;

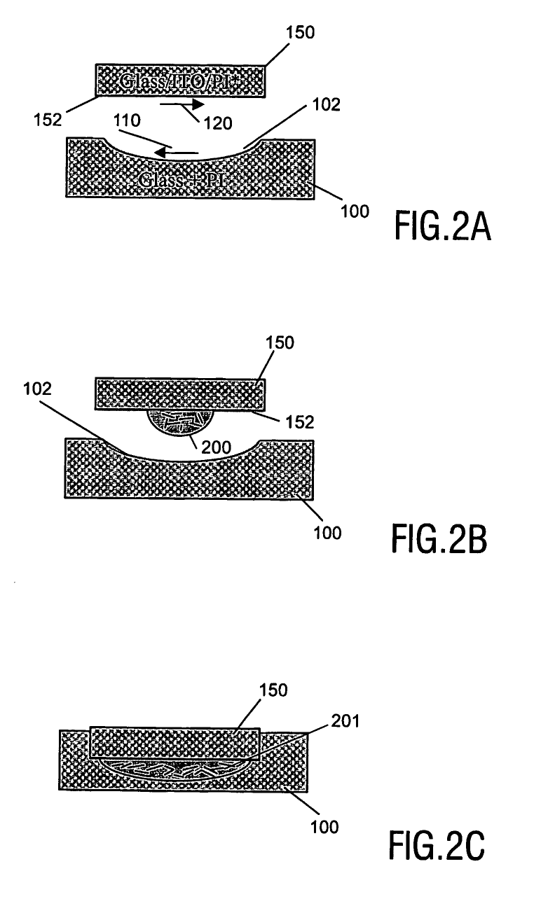

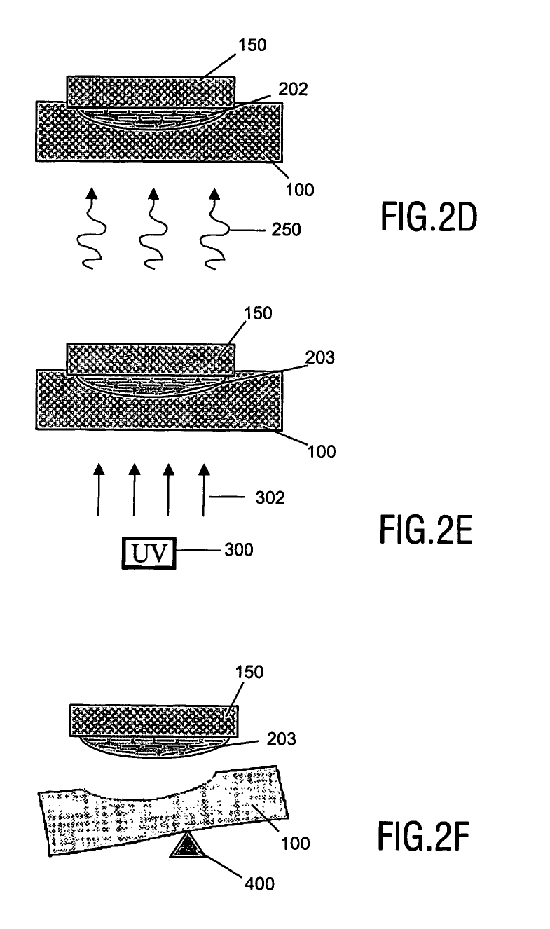

FIGS. 2A-2F illustrate method steps in the formation of a first portion of a liquid crystal lens in accordance with a preferred embodiment of the present invention;

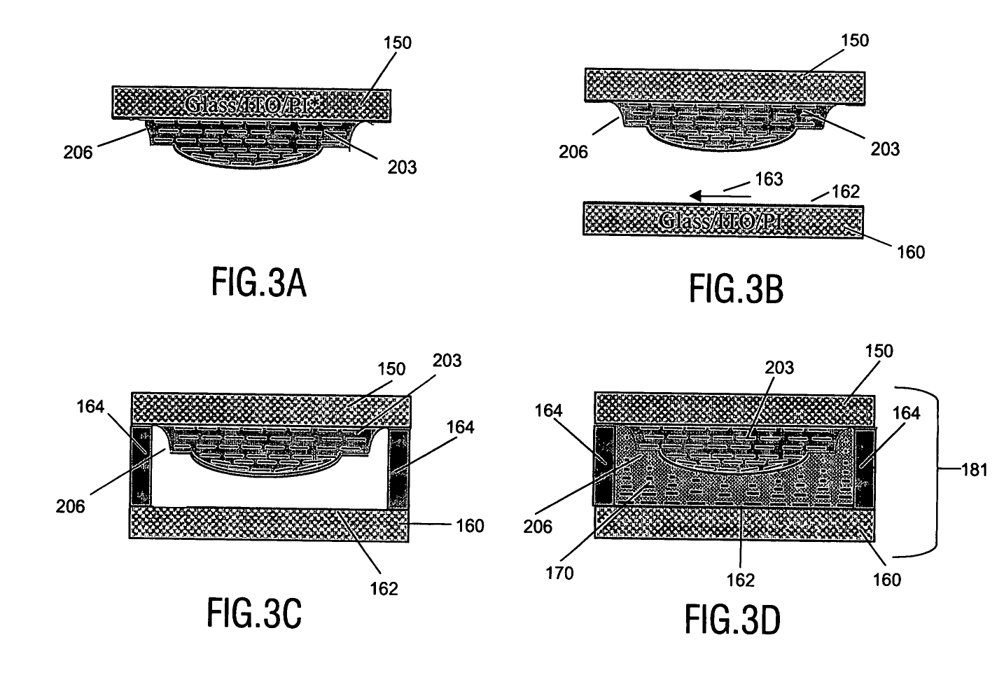

FIGS. 3A-3D illustrate method steps in the formation of the final portion of a liquid crystal lens in accordance with a preferred embodiment of the present invention;

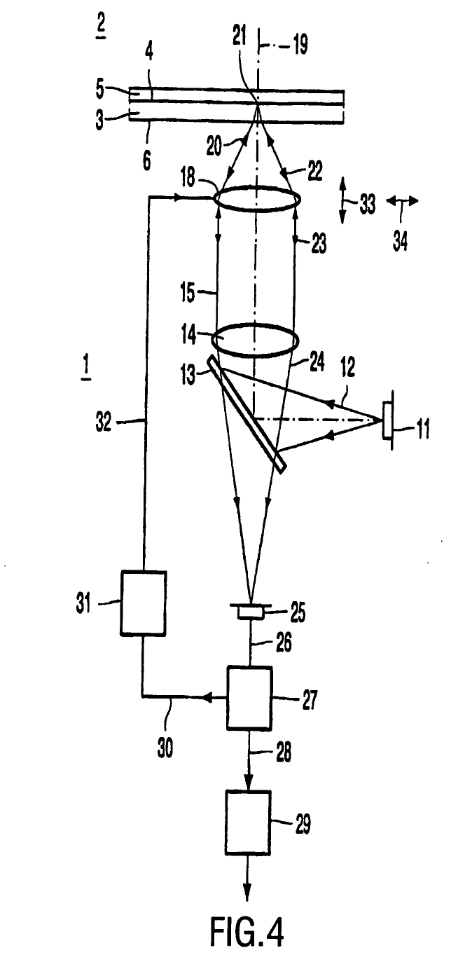

FIG. 4 illustrates a device for scanning an optical record carrier including a liquid crystal lens in accordance with an embodiment of the present invention;

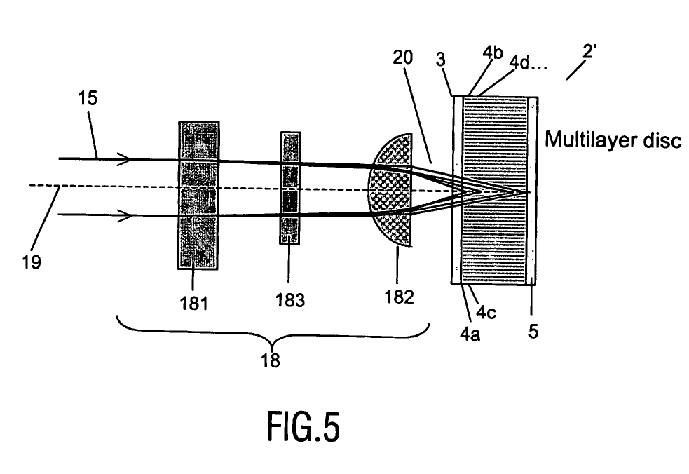

FIG. 5 illustrates how the optical system of the scanning device shown in FIG. 4 may be used with different polarization of light to scan different layers within a dual layer optical record carrier; and

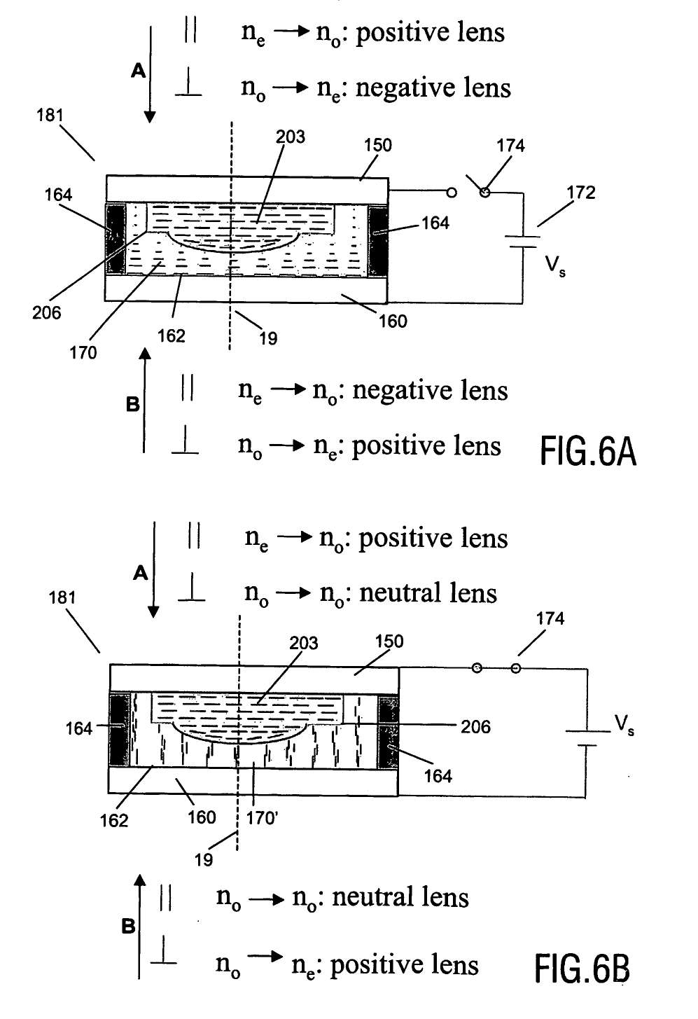

FIGS. 6A and 6B show cross sectional views of the liquid crystal lens illustrated in FIG. 1, with different orientations of the second layer of liquid crystal.

Optical components (or portions of optical components, optical elements) can include curved surfaces so as to focus light (e.g. a convex lens) or disperse light (e.g. a concave lens). Birefringent optical components with curved surfaces will provide different focussing or dispersive effects, dependent upon the angle at which the polarized radiation beam is incident on the optical component.

Equally, optical functions of other components are provided by other shaped (i.e. non-planar) surfaces such as step functions and gratings.

The present inventors have realized that, by providing an additional birefringent material adjacent to the curved (or otherwise shaped) surface, with the orientation of the birefringence of the additional material being able to be altered in a controlled manner, then it is possible to controllably alter the optical functions (e.g. the power of the lens formed by the curved surface) of the optical component. Further, as birefringent materials provide different refractive indices to different polarisations of light, then different functions may also be realized by providing different polarisations of light incident upon the optical component. Thus, such an optical component can provide different optional functionality by both changing the angle of incidence of the polarized radiation, and also by altering the orientation of at least one of the birefringent layers.

Consequently, for differently shaped surfaces, such as step structures and gratings, the optical function of the components can be controllably altered by changing the orientation of the additional birefringent material. Further, as both materials are birefringent different optical functions can also be realized by providing light at different incident polarisations.

In inorganic birefringent materials (e.g. a crystal such as calcite) the atomic structure is non-symmetric. This leads to an anisotropy in the physical constants of materials in different directions. One of those is the refractive index. Consider a polarized beam of light traversing along different optical axis. There will be one optical axis in which a different refractive index will be observed upon traversing perpendicularly and parallel to the optical axis. In general, but not always, two out of three axes have a refractive index that is higher than the refractive index of the third axis.

In organic crystals, such as a liquid crystal, a similar phenomenon occurs although one cannot talk about a difference in the atomic structure. Generally, although not always, two out of three axes have a refractive index that is lower than in the third axis.

The direction in which the molecules of a liquid crystal are aligned is called the director. Light propagating with its plane of polarization parallel to the director experiences the extraordinary refractive index, nₑ.

FIG. 1 illustrates an optical component 181 in accordance with a preferred embodiment of the present invention. The optical component 181 comprises a first layer of birefringent material 203 shaped as a lens. In this particular embodiment, the birefringent material 203 is shaped as a planoconvex lens, the convex portion of the lens being defined by a curved surface 206. The lens is formed as a solid body e.g. a polymerized liquid crystal.

The planar side of the lens is connected to a transparent electrode 150. The electrode is formed of a glass substrate covered with a layer of the transparent conductor ITO (Indium Tin Oxide).

A layer 170 of a second birefringent material separates the first birefringent material 203 from a second transparent electrode 160. The second electrode is again formed from glass and ITO. The second birefringent material 170 is arranged such that the orientation of the birefringent properties of the material can be controllably altered.

In this particular example, both of the birefringent materials are formed from liquid crystal. The ridged body of the first birefringent material is formed of a polymerized liquid crystal. The second birefringent material is a liquid crystal in the nematic phase. The molecules of the second birefringent material are arranged to be movable between two different orientations.

The first orientation of the nematic liquid crystal is determined by one or more alignment layers placed on at least one of the surfaces surrounding the nematic liquid crystal. The alignment layers here are formed of polyimide (PI). In this particular embodiment, two alignment layers are utilized. Each alignment layer is on an opposite surface of the enclosure surrounding the liquid crystal. Each of these surfaces extends substantially perpendicularly to the optical axis 19 (at least in the immediate vicinity of the optical axis 19). In particular, a first alignment layer 162 is located on the internal surface of the electrode 160. The other alignment layer is placed on the surface opposite to the electrode i.e. upon the curved surface 206.

These alignment layers can take any preferred orientation with respect to each other e.g. they could be parallel, or indeed at any predetermined angle with respect to each other. The directors within the liquid crystal tend to align with the orientation of the alignment layer. This then defines the first orientation of the directors i.e. of the molecules within the liquid crystal (and hence defines the orientation of the birefringent properties of the material 170). Further, these alignment layers can be orientated at any predetermined angle with respect to the orientation of the birefringent material within the first layer 203.

In this particular embodiment, the first material is aligned with directors substantially perpendicular to the optical axis. The alignment layer on the first material is also orientated so as to be perpendicular to the optical axis. Further, it is oriented so as to be simultaneously perpendicular to the orientation of the bireringent material in the first layer 203. In contrast, the alignment layer 162 upon the electrode is arranged so as to be parallel to the alignment of the first material (and again also perpendicular to the optical axis 19).

In consequence, as the two alignment layers are oriented at 90° to each other, the liquid crystal in the nematic phase forming the second layer 170 will be arranged in the twisted nematic state. In other words, the directors of the liquid crystal rotate with distance along the optical axis. The directors of the liquid crystal in the second layer adjacent to the alignment layer 162 will be parallel to the directors in the first layer 203. However as a function of distance along the optical axis 19, the orientation of the directors in the second layer 170 gradually changes, with the directors gradually rotating until, at the curved interface 206, the directors are perpendicular to the directors of the first layer 203.

This 90° rotation of directors within the second layer means that the birefringence of the portion of the layer adjacent to the electrode 160 will be different to that portion adjacent to the curved interface 206. In particular, the birefringent properties will be rotated through the same 90° experienced by the directors. Further, polarized radiation passing through the optical component will also be rotated by 90°.

In this particular embodiment, the optical component also comprises an actuation means (172, 174), arranged to change the overall orientation of the second layer 170. In this particular embodiment, the first orientation of the layer 170 is defined by the alignment layers. However, the second orientation is provided by the actuating means acting to apply an electric field across the second layer 170. The directors within the second layer 170 will then align with the electric field (provided it is large enough). In this particular example, the electric field is arranged so as to be parallel to the optical axis 19. The electric field is provided by placing a voltage Vₛ across the two electrodes 150, 160. The voltage Vₛ is provided to the electrodes 150, 160 by the voltage source 172 when the switch 174 is closed.

Spacers 164 act to define the width of the second layer 170, and to enclose the liquid crystal of the second layer. These spacers can be formed of any desired material, and can be formed of a transparent material such as glass or foil.

FIGS. 6A and 6B illustrate this embodiment of the optical component, with the second layer 170 in respectively the first orientation and the second orientation. Detailed explanation of the effect of changing the orientation of the second layer is provided below with reference to these figures.

FIGS. 2A-2F illustrate respective steps in forming a first portion of an optical component in accordance with a preferred embodiment of the present invention. In this particular instance, the optical component includes a liquid crystal birefringent lens.

In the first step, shown in FIG. 2A, mould 100 is provided, the mould having a shaped surface 102 which subsequently serves to define a portion of the shape of the resulting optical component. In this particular instance, the liquid crystal is ultimately photopolymerised, and consequently the mould is formed of a material transparent to the radiation used to polymerize the liquid crystal e.g. glass.

An alignment layer 110 is arranged on the curved surface 102, so as to induce a predetermined orientation (indicated by the arrow direction 110) in the liquid crystal subsequently placed upon the alignment layer.

In this particular example, the alignment layer is a layer of polyimide (PI). The polyimide may be applied using spincoating from a solution. The polyimide may then be aligned so as to induce a specific orientation (this orientation determining the resulting orientation of the liquid crystal molecules). For instance, a known process is to rub the polyimide layer with a non-fluff cloth repeatedly in a single direction so as to induce this orientation (110).

A substrate 150, which in this particular embodiment will form part of the optical component, comprises a layer of ITO upon a glass substrate. A bonding layer 120 is applied to a first surface 152 of the substrate 150. The bonding layer is arranged to form a bond with the liquid crystal. In this particular instance, the bonding layer is also an alignment (or orientation) layer comprising polyimide. The bonding layer contains reactive groups arranged to form a chemical bond with the liquid crystal molecules, and in this instance has the same type of reactive group as the liquid crystal molecules, such that when photopolymerising the liquid crystal molecules, chemical bonds with the bonding layer on the substrate are also created. This results in very good adhesion between substrate and the liquid crystal layer. The bonding layer may be deposited on the substrate using the same type of process used to deposit and align the alignment layer on the mould 100. The bonding layer, which in this instance also functions as an alignment layer, is oriented in a predetermined orientation (arrow 120) depending upon the desired properties of the resulting liquid crystal components.

The bonding layer is aligned so as to be parallel to the direction 110 of the alignment layer on the mould. Preferably, the orientation of the bonding layer is parallel but in the opposite direction to the orientation of the alignment layer.

As illustrated in FIG. 2B, a compound 200 incorporating one or more liquid crystals is then placed between the first surface 152 of the substrate 150 and the shaped surface 102 of the mould 100.

In this particular example, as illustrated in FIG. 2B, the compound 200 comprises a mixture of two different liquid crystals. These two different liquid crystals have been chosen so as to provide the desired refractive index properties once at least one of the liquid crystals has been polymerized.

A droplet of the liquid crystals 200 is placed on the first surface 152 of the substrate. The compound 200 has been degassed, so as to avoid the inclusion of air bubbles within the resulting optical component. It also avoids the formation of air bubbles from dissolved gases coming out of the solidifying liquid during polymerization, as the shrinkage during polymerization leads to a large pressure decrease inside the polymerizing liquid.

The glass mould is then heated so that the liquid crystal is in the isotropic phase (typically to about 80° C.-120° C.), so as to facilitate the subsequent flow of the liquid crystal into the desired shape.

The substrate and the mould are subsequently brought together, so as to define the shape of the liquid crystal portion 201 of the final resulting optical component (FIG. 2C). In order to ensure that the liquid crystal forms a homogenous layer between the mould and the substrate, a pressure may be applied to push the substrate towards the mould (or vice versa).

The substrate/mould/liquid crystal may then be cooled, for instance down to room temperature for 30 minutes, so as to ensure that the liquid crystal enters the nematic phase, coming from the isotropic phase.

When entering the nematic stage, multi domains may appear in the liquid crystal mixture. Consequently, the mixture can be heated to above the clearing point to destroy the multidomain orientation (e.g. the mixture may be heated for 3 minutes to 105° C.). Subsequently, the mixture may be cooled to obtain a homogenous orientation 202 (FIG. 2D).

The homogenous liquid crystal mixture may then be photopolymerised using light 302 from an ultra violet radiation source 300 (FIG. 2E), for instance by applying a UV-light intensity of 10 mW/cm² for 60 seconds. At the same time, chemical bonds will be formed between the liquid crystal and the bonding layer.

Subsequently, the first element (or portion) of the optical component (150, 203) can be released from the mould 100 (FIG. 2F). This could, for instance, be achieved by slightly bending the mould 100 over a cornered object 400. Alternatively, it could be achieved by pressing a portion of the flat substrate in a flat support, so as to slightly bend the flat substrate. The liquid crystal/substrate element should separate easily from the mould, as a conventional polyimide (without reactive groups) is used on the mould.

The mould can be reused to produce subsequent elements of components, by repeating steps illustrated in FIGS. 2B-2F. Typically, the alignment layer will remain upon the mould 100, and hence does not need to be reapplied.

If desired, a further processing step can be performed to remove the liquid crystal 202 from the substrate 150. However, in most instances it is assumed that the substrate 150 will form part of the final optical component.

FIGS. 3A-3D illustrate successive steps in providing a second birefringent layer, so as to complete the optical component. Again, in this particular embodiment, a liquid crystal is used to provide the second layer.

FIG. 3A shows a first alignment layer (a polyimide) being placed upon the curved surface of the first birefringent layer 203. In this particular embodiment, the alignment layer is orientated so as to be perpendicular to the alignment of the directors within the first birefringent layer 203.

A second substrate 160 is provided substantially parallel to, but spaced apart from, the first portion of the component (150, 203). The substrate 160 is used to form an electrode, and consequently is again formed of glass and ITO. An alignment layer 162 is placed upon the surface of the substrate 160 adjacent to the curved surface 206 of the first layer 203. The alignment layer 162 is again formed of polyimide (PI). However, in this instance, the polyimide layer 162 is arranged to be parallel to the directors in the first layer 203.

As shown in FIG. 3C, spacers 164 are arranged to space the two substrates 150, 160. The length of the spaces defines the distance between the substrate 150, 160, and hence the thickness of the second layer of birefringent material. The spacers are ultimately arranged, along with the substrates 150 and 160, and the first layer 203, so as to enclose the second birefringent layer 170. Consequently, spacers are glued all around the periphery of the substrates 150, 160, with only a fill hole and an air hole being left.

Capillary cell filling is then used to fill the enclosed space via the fill hole. Subsequently, the fill hole and the air release hole are closed (e.g. using a plug or glue), so as to form the resulting optical component 181. As indicated in FIG. 3D, the second layer 170 will orient so as to align with the alignment layer in the immediate vicinity. Consequently, as the alignment layers utilized were perpendicular to each other, the second layer 170 exists in the twisted nematic state.

Using the above manufacturing method, an optical component has been formed made of two birefringent materials between transparent conductive layers. The second birefringent material is able to switch the polarization of the incoming light beam actively by applying a voltage to the conductive layers. The other birefringent layer can be a passive layer. The shaped interface between the two layers can be of any desired shaped that provides an optical function, but in the preferred embodiment is a curved surface. The curvature of the surface is of optical quality to minimize aberrations.

In this particular preferred embodiment, so as to provide a multifocal lens, the two materials have been selected such that the ordinary and extraordinary refractive indices of the active layer 170 are respectively equal to the ordinary and extraordinary refractive indices of the passive layer.

The voltage (Vₛ) that can be applied to the conductive layers is sufficient so as to completely cancel the in-plane twist of the twisted nematic state, and lead to the directors being aligned with the electric field.

The result is an optical component, generally similar to that illustrated in FIG. 1.

A suitable polyimide for use in the alignment layers is OPTMER AL-1051 supplied by Japan Synthetic Rubber Co., whilst Durimide 7505 by Arch Chemical can be used as an appropriate reactive polyimide with methacrylate groups as the bonding layer.

The material used for the first (passive) layer preferably comprises a reactive liquid crystal material. Preferably, the mesogenic group with the liquid crystal is end or side capped by one or more polymerizable groups. The material is able to exhibit a nematic phase within a certain (preferably relatively broad) temperature range. The polymerizable group can be a meth-acrylate, an acrylate, an oxirane, an oxitane, a vinyl ether, or any other reactive group.

As mentioned above, in the preferred embodiment a mixture of two liquid crystals was utilized in the first layer 203 to obtain the desired nₑ and nₒ. The two liquid crystals utilized were 1,4-di(4-(3-acryloyloxypropyloxy)benzoyloxy)-2-methylbenzene (RM 257) and RM 82, both from Merck, Darmstadt, Germany. The photoinitiator used to ensure the photo polymerisation of the liquid crystals in the first layer 203 was Irgacure 651, obtainable from Ciba Geigy, Basel, Switzerland.

The second layer (170) is preferably a nematic liquid crystal. The second layer can be formed of E7 (a cyanobiphenyl mixture with a small portion of cyanotriphenyl compound).

FIG. 4 shows a device 1 for scanning an optical record carrier 2, including an objective lens 18 according to an embodiment of the present invention. The record carrier comprises a transparent layer 3, on one side of which an information layer 4 is arranged. The side of the information layer facing away from the transparent layer is protected from environmental influences by a protection layer 5. The side of the transparent layer facing the device is called the entrance face 6. The transparent layer 3 acts as a substrate for the record carrier by providing mechanical support for the information layer.

Alternatively, the transparent layer may have the sole function of protecting the information layer, while the mechanical support is provided by a layer on the other side of the information layer, for instance by the protection layer 5 or by a further information layer and a transparent layer connected to the information layer 4. Information may be stored in the information layer 4 of the record carrier in the form of optically detectable marks arranged in substantially parallel, concentric or spiral tracks, not indicated in the Figure. The marks may be in any optically readable form, e.g. in the form of pits, or areas with a reflection coefficient or a direction of magnetization different from their surroundings, or a combination of these forms.

The scanning device 1 comprises a radiation source 11 that can emit a radiation beam 12. The radiation source may be a semiconductor laser. A beam splitter 13 reflects the diverging radiation beam 12 towards a collimator lens 14, which converts the diverging beam 12 into a collimated beam 15. The collimated beam 15 is incident on an objective system 18.

The objective system may comprise one or more lenses and/or a grating. The objective system 18 has an optical axis 19. The objective system 18 changes the beam 17 to a converging beam 20, incident on the entrance face 6 of the record carrier 2. The objective system has a spherical aberration correction adapted for passage of the radiation beam through the thickness of the transparent layer 3. The converging beam 20 forms a spot 21 on the information layer 4. Radiation reflected by the information layer 4 forms a diverging beam 22, transformed into a substantially collimated beam 23 by the objective system 18 and subsequently into a converging beam 24 by the collimator lens 14. The beam splitter 13 separates the forward and reflected beams by transmitting at least part of the converging beam 24 towards a detection system 25. The detection system captures the radiation and converts it into electrical output signals 26. A signal processor 27 converts these output signals to various other signals.

One of the signals is an information signal 28, the value of which represents information read from the information layer 4. The information signal is processed by an information processing unit for error correction 29. Other signals from the signal processor 27 are the focus error signal and radial error signal 30. The focus error signal represents the axial difference in height between the spot 21 and the information layer 4. The radial error signal represents the distance in the plane of the information layer 4 between the spot 21 and the center of a track in the information layer to be followed by the spot.

The focus error signal and the radial error signal are fed into a servo circuit 31, which converts these signals to servo control signals 32 for controlling a focus actuator and a radial actuator respectively. The actuators are not shown in the Figure. The focus actuator controls the position of the objective system 18 in the focus direction 33, thereby controlling the actual position of the spot 21 such that it coincides substantially with the plane of the information layer 4. The radial actuator controls the position of the objective lens 18 in a radial direction 34, thereby controlling the radial position of the spot 21 such that it coincides substantially with the central line of track to be followed in the information layer 4. The tracks in the Figure run in a direction perpendicular to the plane of the Figure.

The device of FIG. 4 in this particular embodiment is adapted to scan also a second type of record carrier having a thicker transparent layer than the record carrier 2. The device may use the radiation beam 12 or a radiation beam having a different wavelength for scanning the record carrier of the second type. The NA of this radiation beam may be adapted to the type of record carrier. The spherical aberration compensation of the objective system must be adapted accordingly.

FIG. 5 illustrates an optical component 181 in accordance with a preferred embodiment of the present invention in use within the scanning device 1. FIGS. 6A and 6B illustrate the two extreme orientations of the second layer of the liquid crystal (although the liquid crystal is in fact continuously variable in a controlled manner between these two extremes by varying the voltage applied between zero and Vₛ).

As shown in FIG. 5, the optical component 181 can be placed within the objective system 18 of a scanning device. By appropriate control of the polarisation of the parallel beam 15, as well as by controlling the orientation of the second layer 170 within the device, the objective system 18 can be used to scan at different layers 4a, 4b, 4c, 4d . . . within a multi-layer disc 2′.

The objective system 18 comprises the optical component 181 and a focusing lens 182. The focusing lens 182 is arranged to focus the beam from the optical component 181 (which may be parallel, diverging or converging) to a spot on the correct information layer. The optical component 181 acts to alter the parallel polarised beam 15 to the correct diverging, converging, or parallel state dependent upon the desired information layer 4a, 4b, 4c, 4d, . . . to be scanned. Optionally, the objective system 18 may also comprise a polariser for polarisation selection of the beam from the optical element 181 (in some instances the beam from the optical element may be split into two directions, depending upon the state of the optical component).

FIG. 6A illustrates the lens 181 with the second layer 170 in the twisted nematic state (i.e. no voltage is applied to the electrodes 150, 160). In FIG. 6B, a voltage Vₛ has been applied so as to induce an electric field between the electrodes 150, 160. The electric field is high enough for complete cancellation of the in-plane twist of the birefringent layer 170.

It will be appreciated that the optical properties of the lens 181 will vary depending upon the orientation of the layer 170. Further, the optical properties will of course vary depending upon the refractive indices between the layers. In this particular embodiment, the refractive indices of the birefringent layer 170 have been chosen to match the respective refractive indices (nₒ, nₑ) of the passive layer 203.

The optical function provided by the lens 181 will vary in dependence upon the polarisation of the incoming light (e.g. whether the polarisation state of the incoming light is parallel to the direction of the directors within the passive layer 203, or perpendicular to the direction of the directors within the passive layer 203), and upon the direction of the incident light i.e. whether the light is incident first upon the passive layer 203 (as indicated by the arrow A), or whether the light is incident first upon the active layer 170 (as indicated by the arrow B). Using the notation that the “off state” corresponds to no voltage being applied (as shown in FIG. 6A), and the “on state” corresponds to a voltage being applied sufficient to completely cancel the in-plane twist (i.e. FIG. 6B), then the following conditions can be seen to exist:

(1) Light Entering the Lens Via the Passive Layer

(Direction A)

(i) Off state and incoming polarization state of the light is parallel to directors of the passive layer on entrance: a shift from nₑ to nₒ results at the interface; the curved surface hence acts as a positive lens. Further in the active layer the polarization is rotated 90°.
(ii) Off state and incoming polarization state of the light is perpendicular to directors of the passive layer on entrance: a shift from nₒ to nₑ results at the interface; the curved surface hence acts as a negative lens. Further in the active layer the polarization is rotated 90°.
(iii) On state and incoming polarization state of the light is parallel to the directors of the passive layer on entrance: a shift from nₑ to nₒ results at the interface; the curved surface hence acts as a positive lens. No further change of the polarization.
(iv) On state and incoming polarization state of the light is perpendicular to the directors of the passive layer on entrance: No shift occurs (nₒ to nₒ) at the interface; the curved surface hence acts as a neutral lens. No further change of the polarization.
(v) In between the on and off state, refractive indices can be selected between nₑ and nₒ, resulting in a lens that is multi-focal from positive to neutral without the use of an extra selection polarizer. The polarization only changes in the second layer (the active layer). For fluorescent recording this change in polarization is not important.
   (2) Light Entering the Lens Via the Active Layer (Direction B):
(i) Off state and incoming polarization state of the light is parallel to the directors of the passive layer on entrance: polarization is rotated 90° and light will enter the passive layer with a polarization state that is perpendicular to the directors of the passive layer. This means a shift from nₑ to nₒ on the interface between the two layers. In combination with the curvature on the interface between active and passive layer this results in a negative lens.
(ii) Off state and incoming polarization state of the light is perpendicular to the directors of the passive layer on entrance: polarization is rotated 90° and so light will enter the passive layer with a polarization state that is parallel to the directors of the passive layer. This means a shift from nₒ to nₑ at the interface between the two layers. In combination with the curvature on the interface between active and passive layer this results in a positive lens.
(iii) On state and incoming polarization state of the light is parallel to the directors of the passive layer on entrance: no rotation of the polarization. A shift from nₒ to nₑ results at the interface; the curved surface hence acts as a positive lens.
(iv) On state and incoming polarization state of the light is perpendicular to the directors of the passive layer on entrance: no rotation of the polarization. No shift occurs (nₒ to nₑ) at the interface; the curved surface hence acts as a neutral lens.
(v) In between the on and the off state, partial polarization shifts will occur and refractive indices can be selected between nₑ and nₒ. Because of the partial polarization shift the laser beam will enter the passive layer with a polarization state that is not fully perpendicular nor fully parallel (the light ray is dissolved in two directions when the laser beam enters the passive layer). For this reason a polarization selection should be used after the element, to enable multi-focal behavior without having the result of both polarizations at a time. This polarization selection can be done with a separate polarizer.

It will be appreciated that the above embodiments are described by way of example only, and that various alternatives will be apparent to the skilled person.

Whilst specific examples of materials suitable for forming the optical component have been described, and particular manufacturing steps, these are again provided by way of example only.

The mould used in the manufacturing process may be formed of any material, including rigid materials such as glass.

Further, the shaped surface of the mould may be dimensioned so as to allow for any change in shape or volume of the liquid crystal material during the method. For instance, typically liquid crystal monomers shrink slightly upon polymerisation, due to double bonds within the liquid crystal being reformed as single bonds. By appropriately making the optical component shaped defined by the substrate and the mould slightly oversize, an appropriately sized and shaped optical component can be produced.

Whilst the substrates have been seen in this particular example as comprising a single sheet of glass, with two flat, substantially parallel sides, it will be appreciated that the substrates can in fact be any desired shape.

An extra adhesion layer may be applied to the mould and/or substrate (prior to deposition of the bonding layer onto the substrate and the orientation layer to the mould), so as to make sure that the applied layers are well attached to the mould and the substrate. For instance, organosilanes may be used to provide this adhesion layer. For the substrate an organosilane comprising a methacrylate group may be used and for the mould an organosilane comprising an amine end group may be used.

It will be appreciated that the above described optical components are also described by way of example only. An optical component (or indeed, an optical element formed according to the present invention i.e. a portion of an optical component) could be formed with different properties to that described above, or of different birefringent materials.

For instance, in the above embodiments, it is assumed that the refractive indices of the second layer 170 of the component 180 are equal to the corresponding refractive indices of the first layer 203. However, it will be appreciated that in fact any values of ordinary and extraordinary refractive indices could be used for each layer. For instance, an optical component could be formed with the ordinary refractive index of one layer equal to the extraordinary refractive index of the other layer.

Equally, whilst in the above embodiments the optical component has been described as having a curved interface between the two materials, it will be appreciated that the interface could in fact be of any shape that provides an optical function. For instance, the interface could be a step structure or a grating structure. In such instances, the optical functions of the components can still be changed by the incident polarisation states and/or the orientation of the second layer.

In the preferred embodiment, it is assumed that the outer surfaces of the optical element (i.e. the surfaces upon which the light enters and exits the element) are two flat, parallel surfaces. However, these surfaces could in fact be any desired shape, including concave or convex.

Equally, the second layer has been generally described as being switchable between two particular orientations, but it will be appreciated that the second layer can in fact be switchable between any number of orientations. Further, the first layer could be of any predetermined orientation, and in fact if desired the first layer could also be an active layer i.e. it too could have a changeable orientation.

Preferably, the active layer(s) is continuously controllably variable between the two predetermined orientations. For instance, in the particular embodiments illustrated, the orientations of the second layer is continuously variable between the two states shown in FIGS. 6A and 6B by providing the appropriate voltage to the two electrodes.

Further, although in the preferred embodiment one of the orientation states of the second layer is seen to be defined by alignment layers substantially perpendicular to the optical axis, it will be appreciated that these alignment layers could in fact be of any predetermined orientation. For instance, the alignment layers could be parallel to the optical axis e.g. by placing the alignment layers upon the internal surfaces of the spacers 164. If desired, no alignment layers could be used to define an orientation of the second layer. Instead, electrodes could be used to define both orientations (for instance by placing another set of electrodes within the spaces 164).

In all of the above embodiments, an optical component is provided comprising at least two adjacent birefringent materials separated by a shaped interface. The orientation of at least one of the birefringent materials may be changed, so as to result in a change of function (e.g. lens strength, or type) of the shaped interface. Consequently, the function of the interface can be changed by changing both the polarisation of the incident light, and by changing the orientation of the birefringent layer. The optical component can thus be used in a range of novel and interesting ways.

1. An optical component comprises a first birefringent layer connected to a second birefringent layer by a shaped interface, an optical axis passing through the first and the second layer, at least the second birefringent layer having molecules movable between a first orientation and a second orientation relative to the optical axis, the refractive index of the second birefringent layer being dependent upon the orientation of the molecules.

2. An optical component as claimed in claim 1, wherein said interface is a curved interface.

3. An optical component as claimed in claim 1, wherein the first birefringent layer has an ordinary axis substantially perpendicular to the optical axis and an extraordinary axis substantially perpendicular to the optical axis.

4. An optical component as claimed in claim 1, wherein at least one of the first layer and the second layer comprises a liquid crystal.

5. An optical component as claimed in claim 1, wherein the second layer comprises a liquid crystal in the nematic phase.

6. An optical component as claimed in claim 1, wherein in the first orientation, the angle of the molecules relative to the optical axis changes as a function of distance along the optical axis.

7. An optical component as claimed in claim 1, wherein the second layer comprises a liquid crystal, with the first orientation corresponding to the liquid crystal being in the twisted nematic phase.

8. An optical component as claimed in claim 1, wherein the second orientation corresponds to the second layer having the extraordinary axis parallel to the optical axis.

9. An optical component as claimed in claim 1, further comprising actuation means, arranged to change the orientation of the molecules.

10. An optical component as claimed in claim 9, wherein said actuation means comprises at least two electrodes arranged to apply an electric field to the second layer.

11. An optical scanning device for scanning an information layer of an optical record carrier, the device comprising a radiation source for generating a radiation beam and an objective system for converging the radiation beam on the information layer, wherein the device comprises an optical component, the optical component comprising a first birefringent layer connected to a second birefringent layer by a shaped interface, an optical axis passing through the first and the second layer, at least the second birefringent layer having molecules movable between a first orientation and a second orientation relative to the optical axis, the refractive index of the second birefringent layer being dependent upon the orientation of the modules.

12. A device as claimed in claim 11, wherein the optical component forms a controllable lens within the objective system.

13. A method of manufacturing an optical component comprising a first birefringent layer and a second birefringent layer, the method comprising:
providing a first birefringent layer with a shaped surface;
providing a second birefringent layer adjacent to the shaped surface of the first birefringent layer;
wherein the molecules of the second birefringent layer are arranged to be movable between a first orientation and a second orientation relative to an optical axis passing through the first birefringent layer and the second birefringent layer.

14. A method as claimed in claim 13, wherein the second birefringent layer is provided by capillary cell filling.

15. A method of manufacturing an optical scanning device for scanning an information layer of an optical record carrier, the method comprising:
providing a radiation source for generating a radiation beam;
providing an objective system for converging the radiation beam on the information layer; and
providing an optical component, the optical component comprising a first birefringent layer connected to a second birefringent layer by a shaped interface, an optical axis passing through the first and the second layer, at least the second birefringent layer having molecules movable between a first orientation and a second orientation relative to the optical axis, the refractive index of the second birefringent layer being dependent upon the orientation of the modules.
